(19) United States
(12) Patent Application Publication
(10) Pub. No.: US 2009/0272422 A1
(43) Pub. Date: Nov. 5, 2009

(54) Solar Cell Design and Methods of Manufacture

(76) Inventor: Delin Li, San Jose, CA (US)

Correspondence Address: Delin Li, 797 Firewood Court, San Jose, CA, 95120, US

(21) Appl. No.: 12/430,114

(22) Filed: Apr. 27, 2009

Related U.S. Application Data
(60) Provisional application No. 61/048,220, filed on Apr. 27, 2008.
(60) Provisional application No. 61/048,218, filed on Apr. 27, 2008.

(51) Int. Cl. H01L 31/042; H01L 31/00

(52) U.S. Cl. 136/244; 136/256

(57) ABSTRACT

A solar cell has a first surface and the second surface areas. The first surface is a semi-cylindrical area or modified semi-cylindrical area. The first surface is a flattened area. Sunlight strikes the semi-cylindrical area of the solar cell surface with a maximum incident angle from sunrise to sunset. A mirror may be attached on the top surface of the solar cell to further improve the efficiency.

This application is to claim priority to U.S. Provisional Application Ser. No. 61/048,220 filed Apr. 27, 2008, and U.S. Provisional Application Ser. No. 61/048,218 filed Apr. 27, 2008.

### FIELD OF THE INVENTION

This invention relates to solar cell design and manufacture for converting solar energy into electrical energy

### BACKGROUND OF THE INVENTION

The solar cell converts sunlight directly into electricity. It is made of special materials called semiconductors. Basically, when light strikes the cell, a certain portion of it is absorbed within the semiconductor material. This means that the energy of the absorbed light is transferred to the energy in the semiconductor. The energy knocks electrons loose, allowing them to flow freely. All solar cells also have one or more electric fields that act to force electrons freed by light absorption to flow in a certain direction. This flow of electrons is a current which could be collected by placing metal contacts on the top and bottom of the solar cell. This current, together with the cell's voltage which is a result of its built-in electric field or fields defines the power that the solar cell can produce.

The solar cells are traditionally fabricated using silicon (Si) as a light absorbing which uses wafers of single-crystal or polycrystal silicon with a thickness range of 180-330 um. The wafer goes through several process steps and then be integrated into a module. The solar cell using silicon is expensive due to the high material and process cost. In order to achieve lower cost and improved manufacturability at large scale, thin film technologies have been developed in the last three decades. The main advantage of the thin film solar cell technologies is that they have lower costs than the silicon solar cell. They are typically 100 times thinner than silicon wafer with around 1-3 um thickness of the absorbing layer deposited on relative low cost substrates such as glass, metal foils, and plastics. They could be continuously deposited over large areas at lower temperatures. They can tolerate higher impurities of the raw materials. They can be easily integrated into a monolithic interconnected module. For a reference, the semiconductor thin film thickness of the absorbing layer in a thin film solar cell is around 10 times thinner than a human hair. The thin film solar cell typically consist of 5 to 10 different layers whose functions include reducing resistance, forming the p-n junction, reduce reflection losses, and providing a robust layer for contacting and interconnection between cells.

One of the thin film technologies is copper indium gallium diselenide (CIGS) which has been often touted being among the most promising for cost effective power generation. This is due to the fact that the CIGS solar cell uses a 1-3 um thin absorbing layer of the Cu(InGa)Se₂ and a high efficiency has been achieved in the test sample. Another advantage is that the CIGS solar cell and module show excellent long-term stability in the outdoor field tests. In additional to its above advantages, CIGS solar cell also shows high radiation resistance, compared to crystalline silicon solar cell and can be made very lightweight with flexible substrates.

The CIGS solar cell is constructed with Cu(InGa)Se₂/CdS junction in a substrate configuration with a metal such as molybdenum back contact. After depositing Cu(InGa)Se2 absorbing layer on a molybdenum coated substrate and then deposit a n-type CdS layer over the CIGS layer, a junction is formed between Cu(InGa)Se₂ and CdS layers. A transparent ZnO layer is then deposited on the CdS layer and then deposit a front contact layer. A wide variety of thin film deposition methods has been used to make Cu(InGa)Se₂ layer. To determine the most promising technique for the commercial manufacturing of modules, the criteria is that the deposition can be completed at low cost, high yield, and reproducibility. Compositional uniformity over large areas is critical for high yield. Device considerations dictate that the Cu(InGa)Se₂ layer should be at least 1 um thick. For solar cell fabrication, the Cu(InGa)Se₂ is most commonly deposited on a molybdenum coated glass substrate, stainless steel, and other metal substrates.

A research (Hamda A. Al-Thani, et al, “The deposition and characterization of Mo/CuInGaSe2/ZnO solar cell”, National Renewable Energy Laboratory report 7540-01-280-5500, January 2001) reported that CIGS thin film solar cells efficiency is related to the CIGS chemical compositions. The solar cell efficiency was reported between 12.35% and 15.99%. The copper composition is varied from 23.76 at % to 24.84 at %, indium composition is varied from 17.01 at %, to 18.11 at %, gallium composition is varied from 6.38 at % to 7.72 at %, and selenium composition is varied from 50.44 at % to 53.26 at %. It was also reported that the atomic ratio of Ga/(In+Ga) is varied between 0.261 and 0.312.

The first process for making high-quality Cu(InGa)Se.sub.2 thin films for solar cell fabrication is co-evaporation of Cu, In, Ga and Se onto a heated substrate in a vacuum condition. This process was developed in NREL lab and has been used in volume production.

Another technique for growing Cu(InGa)(S,Se).sub.2 thin films for solar cell applications is a two-stage vacuum process where Cu, In, and Ga or their alloy are deposited using sputtering technique on a substrate followed by annealing it in a elevated temperature under atmosphere containing selenium gas or sulfur gas.

Conventional solar cells are typically in the form of a plate structure. The main drawback is that it only receives small portion of the sun energy in the most time of the day. The maximum efficiency is only achieved when the sunlight perpendicularly strikes its surface.

Solar cell with tubular structure was invented. U.S. Pat. No. 3,976,508 to Mlavsky discloses a tubular solar cell comprising a cylindrical silicon with an outer radiation-receiving region of a first conductivity type and an inner region of a second opposite conductivity type separated by a p-n junction. U.S. Pat. No. 3,990,914 to Weinstein and Lee discloses a tubular solar cell using glass substrate. However, these tubular solar cells are difficult for manufacture. The present invention is regarding a solar cell with semi-cylindrical geometry or modified semi-cylindrical geometry which allows the sunlight strikes the surface from sunrise to sunset.

### SUMMARY OF THE INVENTION

The present invention is regarding the solar cell design and methods of manufacture. The solar cell has a semi-cylindrical area or modified semi-cylindrical area and a flattened area. The sunlight strikes the semi-cylindrical area of the solar cell with a maximum incident angle from sunrise to sunset. A mirror may be attached on the top surface of the solar cell to further improve the efficiency. Three geometries of the solar cells are disclosed. The invention also disclosed monolithic integrated solar cells design and manufacture.

### BRIEF DESCRIPTION OF THE DRAWINGS

FIG. 1A show a cross sectional view of the substrate 101 used for fabricating a solar cell. FIG. 1B shows a 3-D view of the substrate 101 used for fabricating a solar cell.

FIGS. 2A-6D illustrate processing steps for manufacturing a solar cell using the substrate shown in FIG. 1.

FIG. 7A shows a cross sectional view of the substrate 201 used for making a solar cell. FIG. 7B shows a 3-D view of the substrate 201 used for fabricating a solar cell.

FIG. 8A shows a cross sectional view of the solar cell fabricated using the substrate 201.

FIG. 8B shows a 3-D view of the solar cell fabricated using the substrate 201.

FIG. 9A shows a cross sectional view of the substrate 301 used for fabricating a solar cell.

FIG. 9B shows a 3-D view of the substrate 301 used for fabricating a solar cell.

FIG. 10A shows a cross sectional view of the solar cell fabricated using the substrate 301.

FIG. 10B shows a 3-D view of the solar cell fabricated using the substrate 301.

FIG. 11A shows a cross sectional view of the substrate 401 used for fabricating monolithic solar cells integration. The top surface of the substrate 401 has semi-cylindrical surface areas 401A and 401B as well as flat surface areas 401C, 401D, and 401E.

FIG. 11B shows a 3-D view of the substrate 401 used for fabricating monolithic solar cells integration.

FIGS. 12A-19B illustrate processing steps for manufacturing a multiple grid array solar cells unit using the substrate 401.

FIG. 20A shows a cross sectional view of the substrate 501 used for fabricating a multiple grid array solar cells unit. FIG. 20B shows a 3-D view of the substrate 501 used for fabricating a multiple solar cells unit.

FIG. 21A shows a cross sectional view of the a multiple solar cells unit fabricated using the substrate 501. FIG. 21B shows a 3-D view of the multiple solar cells unit fabricated using the substrate 501.

FIG. 22A shows a cross sectional view of the substrate 601 used for fabricating a multiple solar cells unit. FIG. 22B shows a 3-D view of the substrate 601 used for making a multiple solar cells unit.

FIG. 23A shows a cross sectional view of the a multiple solar cells unit fabricated using the substrate 601.

FIG. 23B shows a 3-D view of the multiple solar cells unit fabricated using the substrate 601.

FIG. 24 shows a 3-D view of a multiple grid array solar cells unit.

FIG. 25 shows a 3-D view of the mirrors with the frame.

FIG. 26 shows the 3-D view after attaching the mirrors with its frame on the multiple solar cells unit.

FIG. 27A shows a 3-D view of the solar cells with mirrors after removing the mirror frame.

FIG. 27B shows cross sectional view of the multiple solar cells unit with mirrors attachment.

FIG. 28 shows a metal plate for fabricating mirrors.

FIG. 29 shows the mirrors base after etch of the metal plate.

FIG. 30A shows a cross sectional view of the mirror after depositing coatings on the etched metal plate to form mirrors.

FIG. 30B shows a 3-D view of the mirror after depositing coatings on the etched metal plate.

### DESCRIPTION OF THE INVENTION

It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually and appropriately detailed system. It may be noted that, as used in the specification and the appended claims, the singular forms “a”, “an”, and “the” include plural referents unless the context clearly dictates otherwise. Thus, for example, reference to “a material” may include mixtures of materials; reference to “a compound” may include multiple compounds, reference to “an electroplating” may include multiple steps.

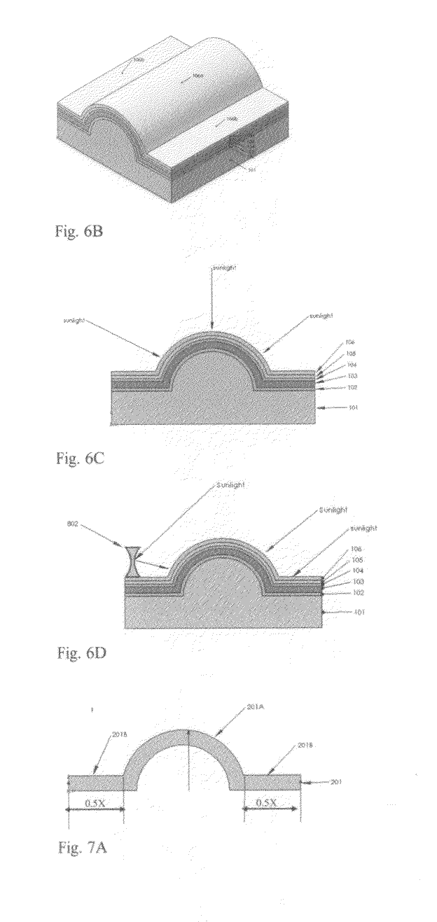

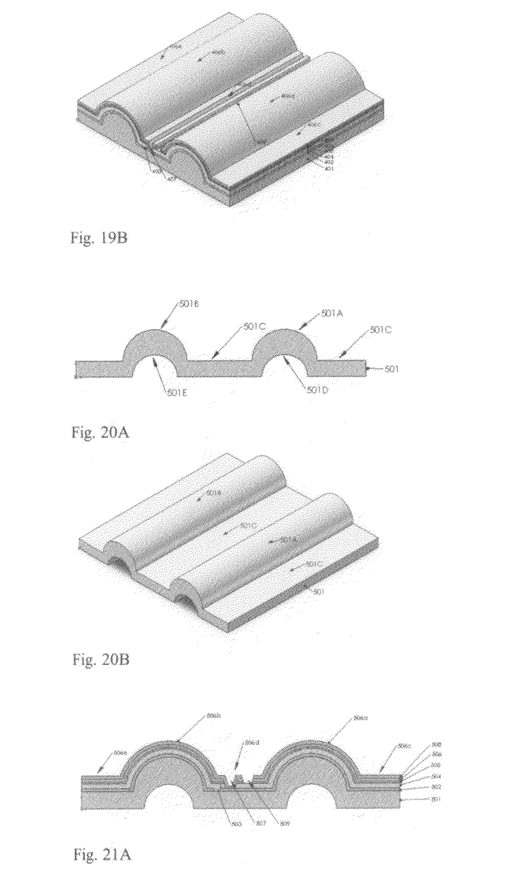

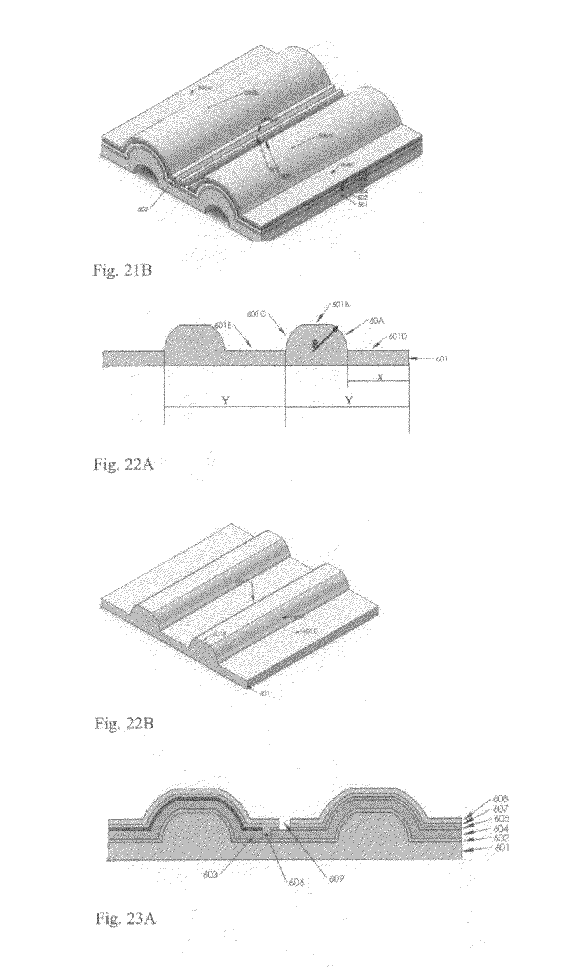

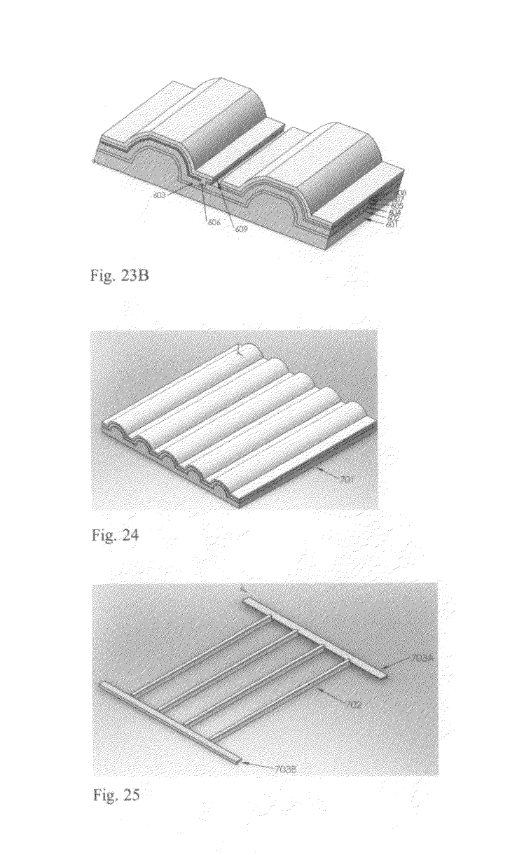

The present invention discloses designs and methods for fabricating solar cells that have a flattened surface area and a semi-cylindrical surface area or modified semi-cylindrical surface area. Seven embodied shapes of the solar cells shown in FIG. 6, FIG. 8, FIG. 10, FIG. 19, FIG. 21, FIG. 23, and FIG. 27 are described. The solar cells may be rigid or flexible. Substrates used for fabricating these solar cells according to the embodiments of the present invention are either rigid or flexible.

Substrates used for fabricating solder cells according to the embodiments of the present invention include at least one material selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass.

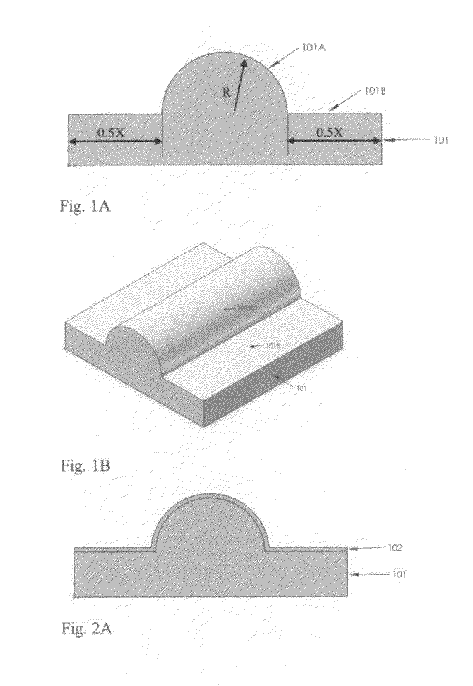

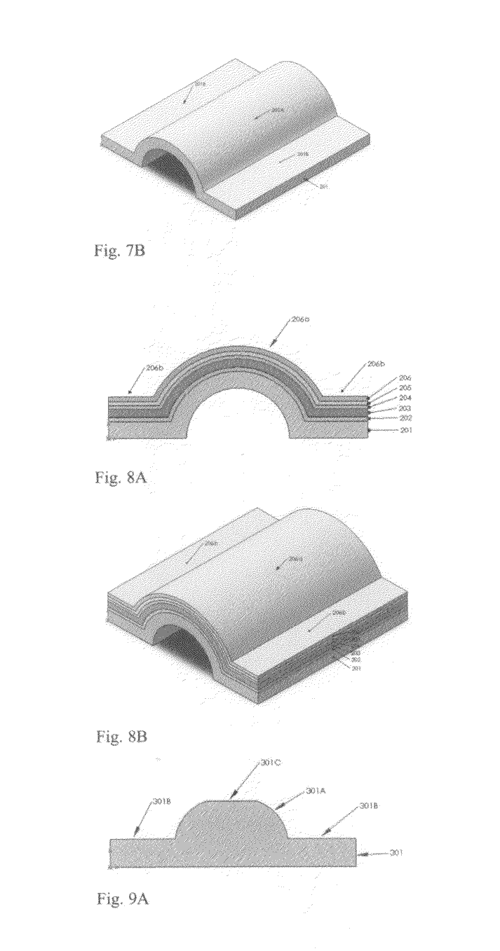

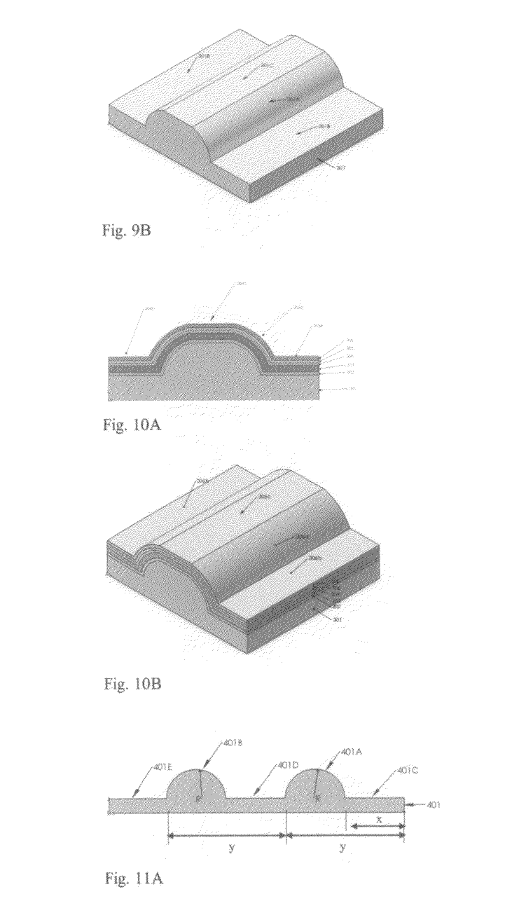

Three basic geometries of the substrates used for fabricating solder cells shown in FIG. 1, FIG. 7, and FIG. 9 are described. The radius of the semi-cylindrical shown in the FIG. 1, FIG. 7, and FIG. 9 may be from 0.5 mm to 50 mm but not limited. The ratio (R/X) between the radius (R) of the semi-cylindrical and the flattened area width (X) shown in the FIG. 1, FIG. 7, and FIG. 9 may be from 0.1 to 10 but not limited. The primary application of these geometric substrates according to the present invention is to make copper indium gallium deselenide (CIGS) thin film solar cell and CdTe thin film solar cell but not limited. The invention may be applied to make silicon based thin film solar cell.

FIG. 1A illustrates a cross-sectional view of an exemplary embodiment of the substrate 101 wherein it comprises a semi-cylindrical surface area 101A and flattened surface areas 101B. FIG. 1B shows a 3-D view of the substrate 101. According to the embodiment of the present invention, the semi-cylindrical area 101A is located in the center and the flattened areas 101B adjoin to the right and left sides of the semi-cylindrical area. The substrate 101 may be one of the materials selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass. In some embodiments the substrate 101 is flexible, in some embodiments the substrate 101 is rigid.

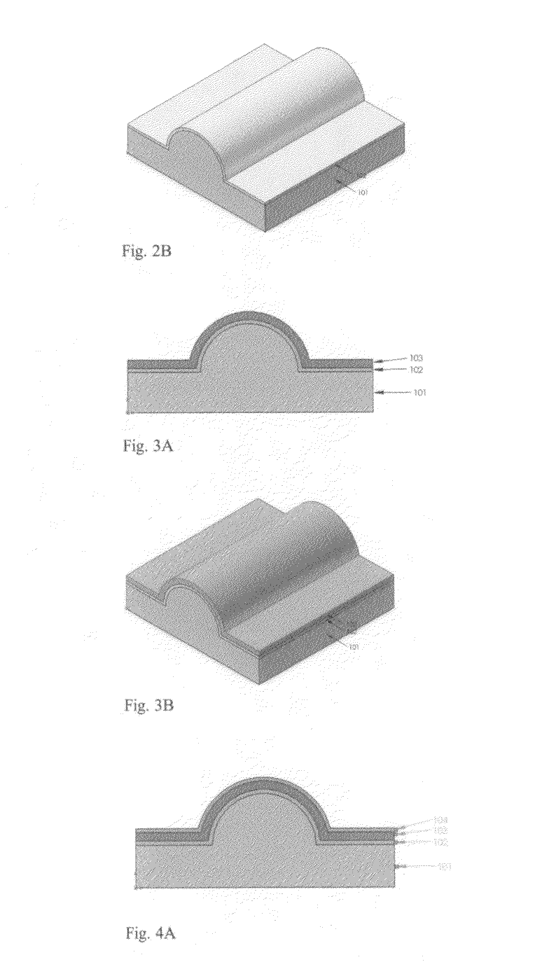

The substrate 101 may be used for making thin film solar cells such as CIGS thin film solar cells, CdTe thin film solar cells, and silicon thin film solar cells. An exemplary embodiment for making CIGS thin film solar cells using the geometric substrate 101 shown in FIG. 1 is described. The first step of the solar cell fabrication is to deposit a back contact electrode 102 on the substrate 101 as shown in FIG. 2. FIG. 2A shows a cross sectional view and FIG. 2B shows a 3-D view after depositing the back contact electrode 102. The back contact electrode 102 may be one of the materials selected from the group consisting of Molybdenum (Mo), chromium (Cr), Titanium (Ti), Tungsten (W), molybdenum/molybdenum-copper (Mo/Mo—Cu), molybdenum/molybdenum-indium (Mo/Mo—In), molybdenum/molybdenum-gallium (Mo/Mo—Ga), molybdenum/molybdenum-selenium (Mo/Mo—Se), chromium/chromium-copper (Cr/Cr—Cu), chromium/chromium-indium (Cr/Cr—In), chromium/chromium-gallium (Cr/Cr—Ga), chromium/chromium-selenium (Cr/Cr—Se), titanium/Titanium-copper (Ti/Ti—Cu), titanium/titanium-indium (Ti/Ti—In), titanium/titanium-gallium (Ti/Ti—Ga), titanium/titanium-selenium (Ti/Ti—Se), tungsten/tungsten-copper (W/W—Cu), tungsten/tungsten-indium (W/W—In), tungsten/tungsten-gallium (W/W—Ga), and tungsten/tungsten-selenium (W/W—Se).

The next step is to form a copper indium gallium deselenide (Cu(InGa)Se₂) thin film semiconductor layer 103 on the back contact electrode 102 as shown in FIG. 3. FIG. 3A is a cross sectional view and FIG. 3B is a 3-D view. The Cu(InGa)Se₂ thin film semiconductor layer may be fabricated using vacuum deposition process, nanoparticle printing process, and electroplating process. One of the vacuum process is co-evaporating Cu, In, Ga, and Se or their alloy on back contact electrode to form Cu(InGa)Se_{2.} thin film semiconductor. Another vacuum process is to deposit Cu, In, Ga, and Se followed by annealing it at a temperature between 400 C and 700 C to form Cu(InGa)Se_{2.} thin film semiconductor. For electroplating process, one method is to sequentially electroplate Cu, In, and Ga or their alloy on back contact electrode followed by annealing it at a temperature between 400 C and 700 C under environment containing selenium gas. Another method is to sequentially electroplate Cu, In, Ga, and Se or their alloy followed by annealing it at a temperature between 400 C and 700 C under an environment with N2 or Ar gas. The electroplating processes have been described in the provisional U.S. patent applications 60/983,936, 60/988,805, and 61/019,247.

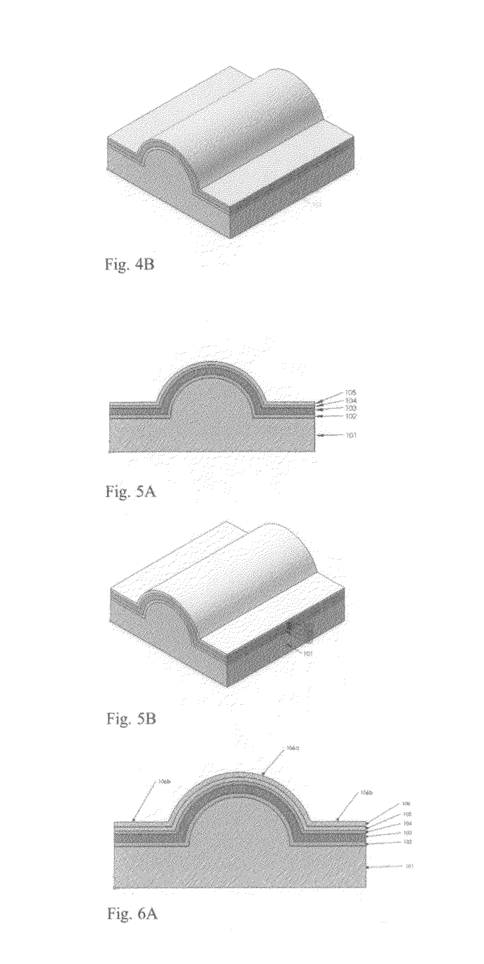

After making the Cu(InGa)Se₂ semiconductor layer 103, a thin film CdS layer 104 is deposited on the Cu(InGa)Se₂ surface to form a p-n junction as shown in FIG. 4. The FIG. 4A shows a cross sectional view and the FIG. 4B shows a 3-D view. The CdS layer may be deposited using a chemical deposition method. A ZnO thin film layer 105 is then deposited on the CdS surface as shown in FIG. 5. A thin film ZnO:Al window layer 106 is deposited on ZnO layer as shown in FIG. 6. FIG. 6A shows a cross sectional view of the solar cell and FIG. 6B shows a 3-D view of the solar cell according to the present invention. The solar cell comprises a semi-cylindrical surface area 106a and flattened surface areas 106b, wherein the semi-cylindrical surface area 106a is located in the center and the flattened surface areas 106b adjoin to the right and left sides of the semi-cylindrical area 106a.

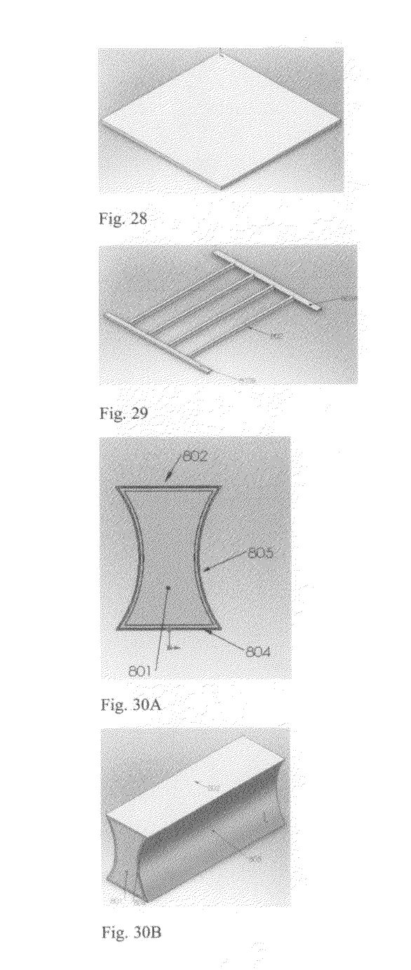

FIG. 6C shows incident angles of the sunlight when it strikes the solar cell surface from sunrise to sunset. As it is illustrated in FIG. 6C, the sunlight almost perpendicularly strikes the semi-cylindrical surface area of the solar cell during the day. A mirror may be attached on the flattened surface of the solar cell to further improve the solar cell efficiency as shown in FIG. 6D. The mirror geometry and manufacturing method are illustrated in FIGS. 28 through 30. Combined with the mirrors and the semi-cylindrical geometry and the flattened surface areas, the solar cell can receive maximum irradiation of the sun energy due to the fact that the sunlight almost perpendicularly strikes its surface from sunrise to sunset.

The basic geometry of the substrate shown in FIG. 1 may be modified to various shapes. For example, FIGS. 7A and 7B show an exemplary embodiment wherein the substrate 201 comprises a hollowed semi-cylindrical area 201A and flattened area 201B. FIG. 7A shows a cross-sectional view and FIG. 7B shows a 3-D view. The hollowed semi-cylindrical area 201A is located in the center and the flattened areas 201B adjoin to the right and left sides of the semi-cylindrical area. The substrate 201 may be one of the materials selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass. In some embodiments the substrate 201 is flexible, in some embodiments the substrate 201 is rigid.

The substrate 201 may be used for making thin film solar cells such as CIGS thin film solar cells, CdTe thin film solar cells, and silicon thin film solar cells. An exemplary embodiment for making CIGS thin film solar cells using the geometric substrate 201 shown in FIG. 7 is described. The first step of the solar cell fabrication is to deposit a back contact electrode 202 on substrate 201. The back contact electrode 202 may be one of the materials selected from a group of Molybdenum (Mo), chromium (Cr), Titanium (Ti), Tungsten (W), molybdenum/molybdenum-copper (Mo/Mo—Cu), molybdenum/molybdenum-indium (Mo/Mo—In), molybdenum/molybdenum-gallium (Mo/Mo—Ga), molybdenum/molybdenum-selenium (Mo/Mo—Se), chromium/chromium-copper (Cr/Cr—Cu), chromium/chromium-indium (Cr/Cr—In), chromium/chromium-gallium gallium (Cr/Cr—Ga), chromium/chromium-selenium (Cr/Cr—Se), titanium/Titanium-copper (Ti/Ti—Cu), titanium/titanium-indium (Ti/Ti—In), titanium/titanium-gallium (Ti/Ti—Ga), titanium/titanium-selenium (Ti/Ti—Se), tungsten/tungsten-copper (W/W—Cu), tungsten/tungsten-indium (W/W—In), tungsten/tungsten-gallium (W/W—Ga), and tungsten/tungsten-selenium (W/W—Se).

The next step is to form a copper indium gallium deselenide (Cu(InGa)Se₂) thin film layer 203 on the back contact electrode 202. The Cu(InGa)Se₂ thin film semiconductor layer may be fabricated using vacuum deposition process, nanoparticle printing process, and electroplating process. One of the vacuum process is co-evaporating Cu, In, Ga, and Se or their alloy on back contact electrode to form Cu(InGa)Se_{2.} thin film semiconductor. Another vacuum process is to deposit Cu, In, Ga, and Se followed by annealing it at a temperature between 400 C and 700 C to form Cu(InGa)Se_{2.} thin film semiconductor. For electroplating process, one method is to sequentially electroplate Cu, In, and Ga or their alloy on back contact electrode followed by annealing it at a temperature between 400 C and 700 C under environment containing selenium gas. Another method is to sequentially electroplate Cu, In, Ga, and Se or their alloy followed by annealing it at a temperature between 400 C and 700 C under an environment with N2 or Ar gas. The electroplating processes have been described in the provisional U.S. patent applications 60/983,936, 60/988,805, and 61/019,247.

After making Cu(InGa)Se₂ semiconductor layer 203, a thin film CdS layer 204 is deposited on the Cu(InGa)Se₂ surface to form a p-n junction. The CdS layer may be deposited using a chemical deposition method. A ZnO thin film layer 205 is then deposited on the CdS surface. A thin film ZnO:Al window layer 206 is deposited on ZnO surface. FIG. 8A shows a cross sectional view of the finished solar cell and FIG. 8B shows a 3-D view of the solar cell using the substrate 201. The solar cell comprises a hollowed semi-cylindrical surface area 206a and flattened surface areas 206b, wherein the hollowed semi-cylindrical surface area 206a is located in the center and the flattened surface areas 206b adjoin to the right and left sides of the semi-cylindrical area 206a.

FIG. 9 show another exemplary embodiment for modifying the basic geometric substrate 101 to a different shape, wherein the substrate 301 comprises flattened surfaces 301b, a top flattened semi-cylindrical surfaces 301a and 301c. FIG. 9A shows a side view of the substrate 301 and FIG. 9B shows a 3-D view of the substrate 301. The substrate includes at least one of the materials selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass. In some embodiments the substrate is flexible, in some embodiments the substrate is rigid.

The substrate 301 may be used for making thin film solar cells such as CIGS thin film solar cells, CdTe thin film solar cells, and silicon thin film solar cells. An exemplary embodiment for making CIGS thin film solar cells using the geometric substrate 301 is described. The first step of the solar cell fabrication is to deposit a back contact electrode 302 on the substrate 301. The back contact electrode 302 may be one of the materials selected from a group of Molybdenum (Mo), chromium (Cr), Titanium (Ti), Tungsten (W), molybdenum/molybdenum-copper (Mo/Mo—Cu), molybdenum/molybdenum-indium (Mo/Mo—In), molybdenum/molybdenum-gallium (Mo/Mo—Ga), molybdenum/molybdenum-selenium (Mo/Mo—Se), chromium/chromium-copper (Cr/Cr—Cu), chromium/chromium-indium (Cr/Cr—In), chromium/chromium-gallium (Cr/Cr—Ga), chromium/chromium-selenium (Cr/Cr—Se), titanium/Titanium-copper (Ti/Ti—Cu), titanium/titanium-indium (Ti/Ti—In), titanium/titanium-gallium (Ti/Ti—Ga), titanium/titanium-selenium (Ti/Ti—Se), tungsten/tungsten-copper (W/W—Cu), tungsten/tungsten-indium (W/W—In), tungsten/tungsten-gallium (W/W—Ga), and tungsten/tungsten-selenium (W/W—Se).

The next step is to form a copper indium gallium deselenide (Cu(InGa)Se₂) thin film layer 303 on the back contact electrode 302. The Cu(InGa)Se₂ thin film semiconductor layer may be fabricated using vacuum deposition process, nanoparticle printing process, and electroplating process. One of the vacuum process is co-evaporating Cu, In, Ga, and Se or their alloy on back contact electrode to form Cu(InGa)Se_{2.} thin film semiconductor. Another vacuum process is to deposit Cu, In, Ga, and Se followed by annealing it at a temperature between 400 C and 700 C to form Cu(InGa)Se_{2.} thin film semiconductor. For electroplating process, one method is to sequentially electroplate Cu, In, and Ga or their alloy on back contact electrode followed by annealing it at a temperature between 400 C and 700 C under environment containing selenium gas. Another method is to sequentially electroplate Cu, In, Ga, and Se or their alloy followed by annealing it at a temperature between 400 C and 700 C under an environment with N2 or Ar gas. The electroplating processes have been described in the provisional U.S. patent applications 60/983,936, 60/988,805, and 61/019,247.

After making Cu(InGa)Se₂ semiconductor layer 303, a thin film CdS layer 304 is deposited on the Cu(InGa)Se₂ surface to form a p-n junction. The CdS layer may be deposited using a chemical deposition method. A ZnO thin film layer 305 is then deposited on the CdS surface. A thin film ZnO:Al window layer 306 is deposited on ZnO surface. FIG. 10A shows a cross sectional view of the finished solar cell and FIG. 10B shows a 3-D view of the solar cell. The solar cell comprises top flattened semi-cylindrical surface areas 306a and 306c, and flattened surface areas 306b, wherein the top flattened semi-cylindrical surface area 306a and 306c are located in the center and the flattened surface areas 306b adjoin to the right and left sides of the flattened semi-cylindrical areas 306a and 306c.

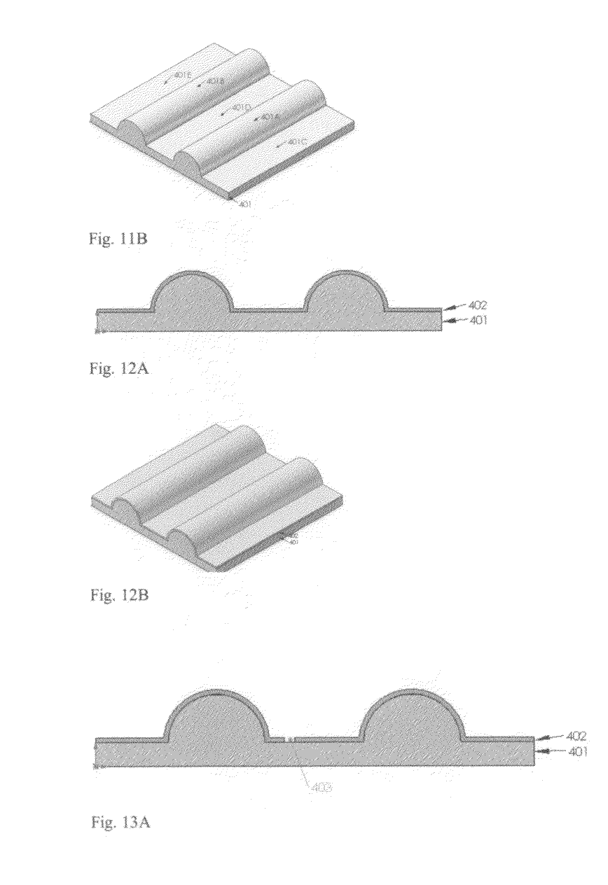

The geometry of the substrate shown in FIG. 1 can be formed as an array format for fabricating multiple grid array thin film solar cells such as multiple CIGS grid array solar cells, CdTe grid array solar cells, and grid array silicon thin film solar cells. An exemplary embodiment for making multiple grid array CIGS thin film solar cells is illustrated in FIG. 11 through FIG. 19. The geometry of the substrate for the exemplary embodiment is shown in FIGS. 11A and 11B, wherein FIG. 11A shows a cross sectional view of the substrate and FIG. 11B shows a 3-D view of the substrate. The substrate 401 shown in FIG. 11 comprises two semi-cylindrical areas 401A and 401B and three flattened areas 401C, 401D, and 401E. The radius of the semi-cylinder shown in the FIG. 11 may be from 0.5 mm to 50 mm but not limited. The ratio between the radius of the semi-cylinder R and the flat area width X may be from 0.1 to 10. The substrate 401 shown in FIG. 11 may be one of the materials selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass. In some embodiments the substrate 401 is flexible, in some embodiments the substrate 401 is rigid.

The processes for fabricating multiple grid array CIGS solar cells using the geometry of the substrate shown in FIG. 11 are described. The first step of the solar cell fabrication is to deposit a back contact electrode 402 on the substrate as shown in FIG. 12. FIG. 12A shows a cross sectional view and FIG. 12B shows a 3-D view. The back contact electrode 402 may be one of the materials selected from a group consisting of Molybdenum (Mo), chromium (Cr), Titanium (Ti), Tungsten (W), molybdenum/molybdenum-copper (Mo/Mo—Cu), molybdenum/molybdenum-indium (Mo/Mo—In), molybdenum/molybdenum-gallium (Mo/Mo—Ga), molybdenum/molybdenum-selenium (Mo/Mo—Se), chromium/chromium-copper (Cr/Cr—Cu), chromium/chromium-indium (Cr/Cr—In), chromium/chromium-gallium (Cr/Cr—Ga), chromium/chromium-selenium (Cr/Cr—Se), titanium/Titanium-copper (Ti/Ti—Cu), titanium/titanium-indium (Ti/Ti—In), titanium/titanium-gallium (Ti/Ti—Ga), titanium/titanium-selenium (Ti/Ti—Se), tungsten/tungsten-copper (W/W—Cu), tungsten/tungsten-indium (W/W—In), tungsten/tungsten-gallium (W/W—Ga), and tungsten/tungsten-selenium (W/W—Se).

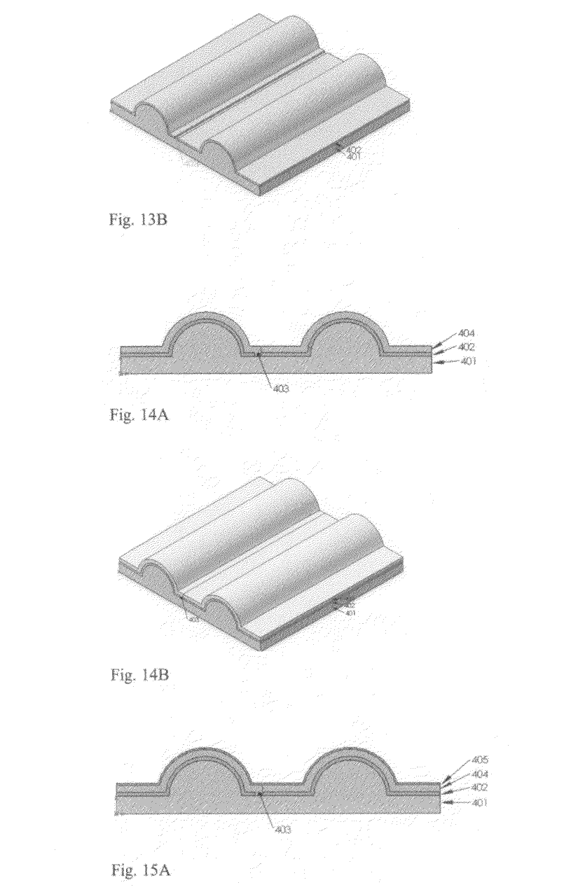

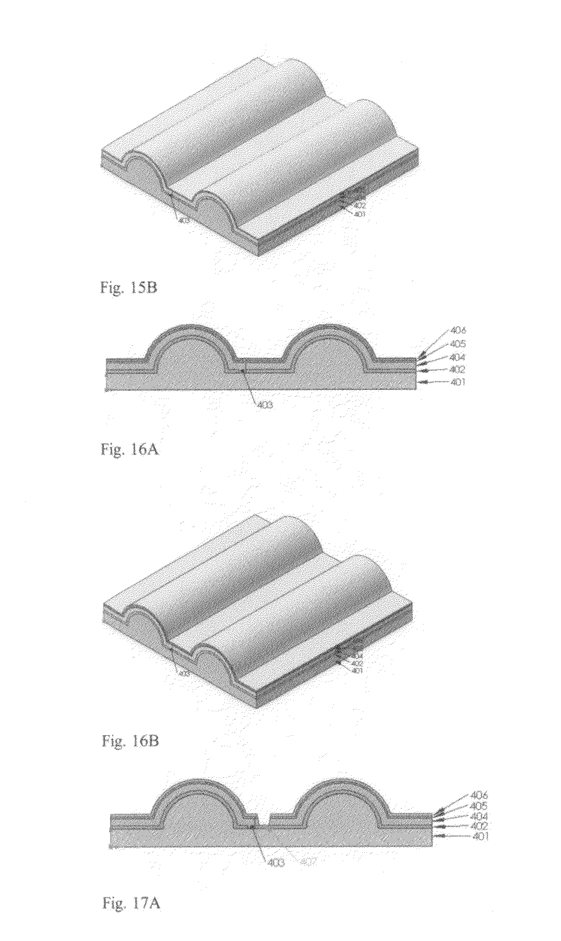

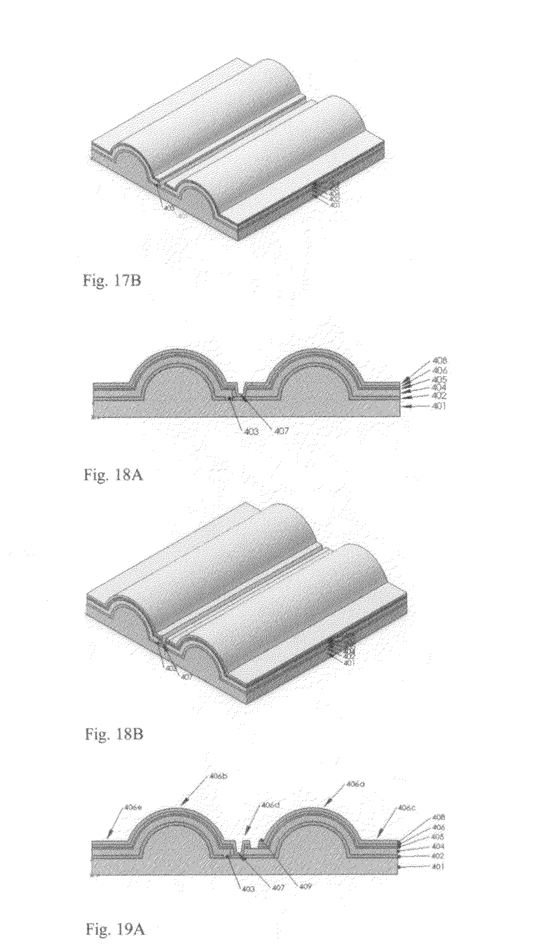

The next step after the back contact electrode deposition is to make patterns 403 as shown in FIG. 13, wherein the back contact electrode 402 is partially removed using laser cutting or mechanical cutting. After making the patterns 403, the next step is to make a copper indium gallium deselenide (Cu(InGa)Se₂) thin film layer 404 as shown in FIG. 14. FIG. 14A shows a cross sectional view and FIG. 14B shows a 3-D view after CIGS layer fabrication. The Cu(InGa)Se₂ thin film semiconductor layer may be fabricated using vacuum deposition process, nanoparticle printing process, and electroplating process. One of the vacuum process is co-evaporating Cu, In, Ga, and Se or their alloy on back contact electrode to form Cu(InGa)Se_{2.} thin film semiconductor. Another vacuum process is to deposit Cu, In, Ga, and Se followed by annealing it at a temperature between 400 C and 700 C to form Cu(InGa)Se_{2.} thin film semiconductor. For electroplating process, one method is to sequentially electroplate Cu, In, and Ga or their alloy on back contact electrode followed by annealing it at a temperature between 400 C and 700 C under environment containing selenium gas. Another method is to sequentially electroplate Cu, In, Ga, and Se or their alloy followed by annealing it at a temperature between 400 C and 700 C under an environment with N2 or Ar gas. The electroplating processes have been described in the provisional U.S. patent applications 60/983,936, 60/988,805, and 61/019,247. After making Cu(InGa)Se₂ semiconductor layer 404, a thin film CdS layer 405 is deposited on the Cu(InGa)Se₂ surface to form a p-n junction as shown in FIG. 15. The CdS layer 405 may be deposited using a chemical deposition method. A ZnO thin film layer 406 is then deposited on the CdS surface as shown in FIG. 16 followed by making patterns 407 as shown in FIG. 17 wherein the ZnO, CdS, and CIGS thin films are partially removed by laser cutting or mechanical cutting. A thin film ZnO:Al window layer 408 is deposited as shown in FIG. 18. The window layer is then patterned by partially removing ZnO:Al as shown in FIG. 19 by laser cutting or mechanical cutting to form the solar cell 1 and solar cell 2 wherein solar cell 1 and solar cell 2 are connected each other. FIG. 19A shows a cross sectional view and the FIG. 19B shows a 3-D view of the monolithic integrated solar cells.

It should be understood that the processes of exemplary embodiment shown in FIG. 11 through FIG. 19 may be used for fabricating multiple grid array solar cells comprising of a first solar cell, a second solar cell, a third solar cell, and up to a N−1 solar cell, and a N solar cell. The N is a numeric number which may be from 2 to multi millions. For example, when a substrate plate is used for fabricating solar cells, the numeric number N may be from several hundred to several thousand depending on the substrate plate dimension which the manufacture equipment can be processed. If a flexible substrate is used for roll-to-roll soar cells fabrication, the numeric number of the N may be up to multi millions depending on the length of the substrate which can be processed by the manufacturing equipment.

FIGS. 20-21 shows another exemplary embodiment for making multiple grid array CIGS thin film solar cells according to the present invention. The geometry of the substrate for the exemplary embodiment is shown in FIGS. 20A and 20B, wherein FIG. 20A shows a cross sectional view of the substrate and FIG. 20B shows a 3-D view of the substrate. The substrate 501 shown in FIG. 20 comprises two hollowed semi-cylindrical areas 501A and 501B and three flattened areas 401C. The radius of the hollowed semi-cylindrical shown in the FIG. 20 may be from 0.5 mm to 50 mm but not limited. The ratio between the radius of the hollowed semi-cylindrical and the flattened area width may be from 0.1 to 10. The substrate 501 shown in FIG. 20 may be one of the materials selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass. In some embodiments the substrate 501 is flexible, in some embodiments the substrate 501 is rigid.

The processes for fabricating multiple grid array CIGS solar cells using the geometry of the substrate shown in FIG. 20 are described. The first step of the solar cell fabrication is to deposit a back contact electrode 502 on the substrate as shown in FIG. 20. The back contact electrode 502 may be one of the materials selected from a group consisting of Molybdenum (Mo), chromium (Cr), Titanium (Ti), Tungsten (W), molybdenum/molybdenum-copper (Mo/Mo—Cu), molybdenum/molybdenum-indium (Mo/Mo—In), molybdenum/molybdenum-gallium (Mo/Mo—Ga), molybdenum/molybdenum-selenium (Mo/Mo—Se), chromium/chromium-copper (Cr/Cr—Cu), chromium/chromium-indium (Cr/Cr—In), chromium/chromium-gallium (Cr/Cr—Ga), chromium/chromium-selenium (Cr/Cr—Se), titanium/Titanium-copper (Ti/Ti—Cu), titanium/titanium-indium (Ti/Ti—In), titanium/titanium-gallium (Ti/Ti—Ga), titanium/titanium-selenium (Ti/Ti—Se), tungsten/tungsten-copper (W/W—Cu), tungsten/tungsten-indium (W/W—In), tungsten/tungsten-gallium (W/W—Ga), and tungsten/tungsten-selenium (W/W—Se).

The next step after the back contact electrode deposition is making patterns 503, wherein the back contact electrode 502 is partially removed using laser cutting or mechanical cutting. After making the patterns 503, the next step is to make a copper indium gallium deselenide (Cu(InGa)Se₂) thin film layer 504. The Cu(InGa)Se₂ thin film semiconductor layer may be fabricated using vacuum deposition process, nanoparticle printing process, and electroplating process. One of the vacuum process is co-evaporating Cu, In, Ga, and Se or their alloy on back contact electrode to form Cu(InGa)Se_{2.} thin film semiconductor. Another vacuum process is to deposit Cu, In, Ga, and Se followed by annealing it at a temperature between 400 C and 700 C to form Cu(InGa)Se_{2.} thin film semiconductor. For electroplating process, one method is to sequentially electroplate Cu, In, and Ga or their alloy on back contact electrode followed by annealing it at a temperature between 400 C and 700 C under environment containing selenium gas. Another method is to sequentially electroplate Cu, In, Ga, and Se or their alloy followed by annealing it at a temperature between 400 C and 700 C under an environment with N2 or Ar gas. The electroplating processes have been described in the provisional U.S. patent applications 60/983,936, 60/988,805, and 61/019,247.

After making Cu(InGa)Se₂ semiconductor layer 504, a thin film CdS layer 505 is deposited on the Cu(InGa)Se₂ surface to form a p-n junction. The CdS layer 505 may be deposited using a chemical deposition method. A ZnO thin film layer 506 is then deposited on the CdS surface followed by making patterns 507 as shown in FIG. 21 wherein the ZnO, CdS, and CIGS thin films are partially removed by laser cutting or mechanical cutting. A thin film ZnO:Al window layer 508 is deposited as shown in FIG. 21. The window layer is then patterned by partially removing ZnO:Al by laser cutting or mechanical cutting to form the solar celll and solar cell 2 wherein solder cell 1 and solar cell 2 are connected each other. FIG. 21A shows a cross sectional view and the FIG. 21B shows a 3-D view of the monolithic integrated solar cells.

It should be understood that the processes of exemplary embodiment shown in FIG. 20 through FIG. 21 may be used for fabricating multiple grid array solar cells comprising of a first solar cell, a second solar cell, a third solar cell, and up to a N−1 solar cell, and a N solar cell. The N is a numeric number which may be from 2 to millions. For example, when a substrate plate is used for fabricating solar cell, the numeric number N may be from several hundred to several thousand depending on the substrate plate dimension which the manufacture equipment can be processed. If a flexible substrate is used for roll-to-roll soar cells fabrication, the numeric number of the N may be up to multi millions depending on the length of the substrate which can be processed by the manufacturing equipment.

FIGS. 22-23 shows another exemplary embodiment for fabrication multiple CIGS grid array solar cells according to the present invention. The geometry of the substrate for the exemplary embodiment is shown in FIGS. 22A and 22B, wherein FIG. 22A shows a cross sectional view of the substrate and FIG. 22B shows a 3-D view of the substrate. The substrate 601 shown in FIG. 22 comprises two top flattened semi-cylindrical areas and flattened areas, wherein one of two top flattened semi-cylindrical comprises three surface areas of 601A, 601B, and 601C. The radius of the top flattened semi-cylindrical shown in the FIG. 22 may be from 0.5 mm to 50 mm but not limited. The ratio between the radius of the top flattened semi-cylindrical and the flattened area width may be from 0.1 to 10. The substrate 601 shown in FIG. 22 may be one of the materials selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass. In some embodiments the substrate 601 is flexible, in some embodiments the substrate 601 is rigid.

The processes for fabricating multiple grid array CIGS solar cells using the geometry of the substrate shown in FIG. 22 are described. The first step of the solar cell fabrication is to deposit a back contact electrode 602 on the substrate as shown in FIG. 22. The back contact electrode 602 may be one of the materials selected from a group consisting of Molybdenum (Mo), chromium (Cr), Titanium (Ti), Tungsten (W), molybdenum/molybdenum-copper (Mo/Mo—Cu), molybdenum/molybdenum-indium (Mo/Mo—in), molybdenum/molybdenum-gallium (Mo/Mo—Ga), molybdenum/molybdenum-selenium (Mo/Mo—Se), chromium/chromium-copper (Cr/Cr—Cu), chromium/chromium-indium (Cr/Cr—In), chromium/chromium-gallium (Cr/Cr—Ga), chromium/chromium-selenium (Cr/Cr—Se), titanium/Titanium-copper (Ti/Ti—Cu), titanium/titanium-indium (Ti/Ti—In), titanium/titanium-gallium (Ti/Ti—Ga), titanium/titanium-selenium (Ti/Ti—Se), tungsten/tungsten-copper (W/W—Cu), tungsten/tungsten-indium (W/W—In), tungsten/tungsten-gallium (W/W—Ga), and tungsten/tungsten-selenium (W/W—Se).

The next step after the back contact electrode deposition is to make patterns 603, wherein the back contact electrode 602 is partially removed using laser cutting or mechanical cutting. After making the patterns 603, the next step is to make a copper indium gallium deselenide (Cu(InGa)Se₂) thin film layer 604. The Cu(InGa)Se₂ thin film semiconductor layer may be fabricated using vacuum deposition process, nanoparticle printing process, and electroplating process. One of the vacuum process is co-evaporating Cu, In, Ga, and Se or their alloy on back contact electrode to form Cu(InGa)Se_{2.} thin film semiconductor. Another vacuum process is to deposit Cu, In, Ga, and Se followed by annealing it at a temperature between 400 C and 700 C to form Cu(InGa)Se_{2.} thin film semiconductor. For electroplating process, one method is to sequentially electroplate Cu, In, and Ga or their alloy on back contact electrode followed by annealing it at a temperature between 400 C and 700 C under environment containing selenium gas. Another method is to sequentially electroplate Cu, In, Ga, and Se or their alloy followed by annealing it at a temperature between 400 C and 700 C under an environment with N2 or Ar gas. The electroplating processes have been described in the provisional U.S. patent applications 60/983,936, 60/988,805, and 61/019,247.

After making Cu(InGa)Se₂ semiconductor layer 604, a thin film CdS layer 605 is deposited on the Cu(InGa)Se₂ surface to form a p-n junction. The CdS layer 605 may be deposited using a chemical deposition method. A ZnO thin film layer 506 is then deposited on the CdS surface followed by making patterns 607 as shown in FIG. 23 wherein the ZnO thin film and CIGS thin film are partially removed by laser cutting or mechanical cutting. A thin film ZnO:Al window layer 608 is deposited as shown in FIG. 23. The window layer is then patterned by partially removing ZnO:Al by laser cutting or mechanical cutting to form the solar celll and solar cell 2 wherein solder cell 1 and solar cell 2 are connected each other. FIG. 23A shows a cross sectional view and the FIG. 23B shows a 3-D view of the monolithic integrated solar cells.

It should be understood that the processes of exemplary embodiment shown in FIG. 22 through FIG. 23 may be used for fabricating multiple grid array solar cells comprising of a first solar cell, a second solar cell, a third solar cell, and up to a N−1 solar cell, and a N solar cell. The N is a numeric number which may be from 2 to millions. For example, when a substrate plate is used for fabricating solar cell, the numeric number N may be from several hundred to several thousand depending on the substrate plate dimension which the manufacture equipment can be processed. If a flexible substrate is used for roll-to-roll soar cells fabrication, the numeric number of the N may be up to multi millions depending on the length of the substrate which can be processed by the manufacturing equipment.

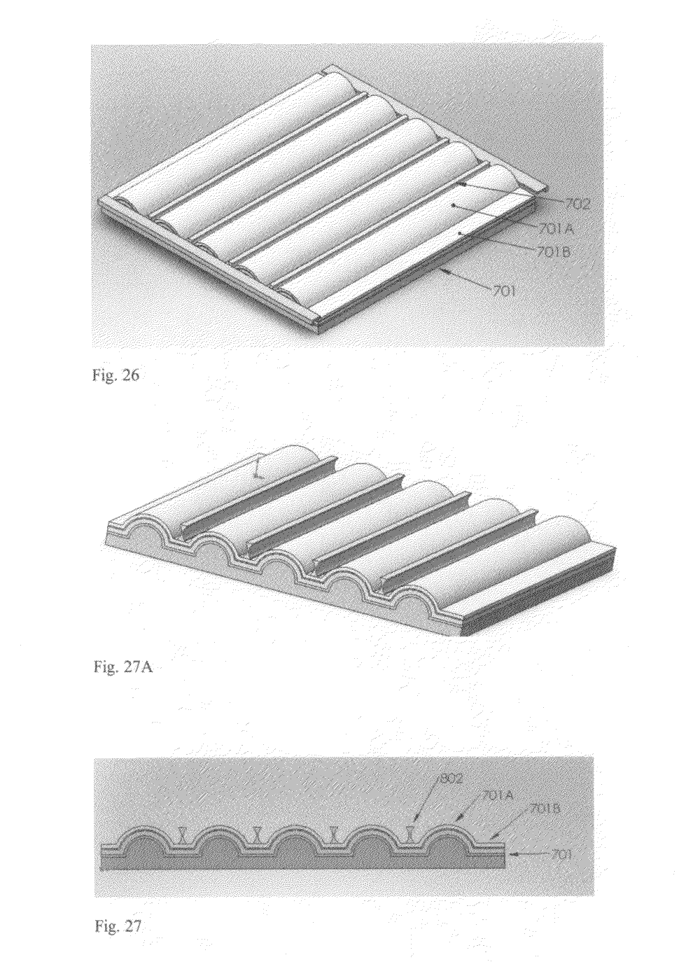

According to the present invention, mirrors may be attached on the surface of the series-connected solar cells to improve the efficiency. FIGS. 24-27 show an exemplary embodiment of the assembly for attaching mirrors on the solar cells surface. FIG. 24 shows a multiple series connected grid array solar cell unit 701 wherein the solar cells comprise arrayed semi-cylindrical areas and flattened areas. The solar cells unit may be CIGS thin film solar cells, CdTe thin film solar cells or silicon thin film solar cells. FIG. 25 shows a mirror array unit comprising of a mirror array 702 and frames 703A and 703B. The mirrors fabrication processes are illustrated in FIGS. 28 through 30. The mirrors unit is aligned and attached on the solar cells surface as shown in FIG. 26, wherein mirror 702 is located between two semi-cylindrical areas on the solar cell unit. The mirror frame 703A and 703B are then removed and the solar cells with the mirrors are shown in FIG. 27. FIG. 27A shows a 3-D view of the solar cells with the attached mirrors and FIG. 27B shows a cross sectional view.

An exemplary embodiment for fabricating mirror arrays is illustrated in FIGS. 28-30. FIG. 28 shows a 3-D view of the substrate on a frame used for fabricating mirrors. The substrates may be one of the materials selected from a group comprising of aluminum, aluminum alloys, kovar metal, stainless steel, plastic, and glass. The first step of the fabrication is to etch the substrate to form mirrors base as shown in FIG. 29, wherein it comprises a mirror array 802 and frames 803A and 803B. Then, coatings are applied on the surface of the mirror base. The first layer of the coating material may be silver, aluminum, titanium, and platinum. The second layer of the coating such as SiO2 is applied over the first coating as shown in FIG. 30, wherein surface 805 is a active mirror surface.

### EXAMPLE 1

A stainless steel sheet was formed to have 5 semi-cylindrical arrays with flattened areas between them. The radius of the semi-cylindrical area was 5 mm. The flattened area between the two semi-cylindrical areas was 6 mm width. The substrate dimension was 100 mm length and 100 mm width Grid array CIGS solar cells were formed on the substrate. The first step was to vacuum deposit a MoCu alloy back contact electrode followed by mechanical cutting to form patterns. Then, Cu(InGa)Se₂ semiconductor layer was formed by co-evaporating process under vacuum condition. CdS thin film was then deposited on the Cu(InGa)Se₂ surface by chemical deposition method. ZnO thin film was then vacuum deposited on the CdS surface followed by second mechanical cutting to form patterns. ZnO:Al thin film was then deposited on the ZnO surface and finally ZnO:Al was partially removed by mechanical cutting. Total 25 solar cells were formed on the substrate with 5×5 grid array format.

### EXAMPLE 2

A soda lime glass substrate was formed to have 5 semi-cylindrical arrays with flattened areas between them. The radius of the semi-cylindrical area was 5 mm. The flattened area width between the two semi-cylindrical areas was 6 mm. The substrate dimension was 100 mm length and 100 mm width. Grid array CIGS solar cells were formed on the substrate. The first step was to vacuum deposit a MoCu alloy back contact electrode followed by mechanical cutting to form patterns. Then, a thin copper layer is deposited on MoCu surface. Cu(InGa)Se₂ semiconductor layer was then formed by sequentially electroplating a stack of Cu/In/Ga/Se followed by annealing it at 550 C for 35 minutes under N2 environment. CdS thin film was then deposited on the Cu(InGa)Se₂ surface by chemical deposition method. ZnO thin film was then deposited on the CdS surface followed by second mechanical cutting to form patterns. ZnO:Al thin film was then deposited on the ZnO surface and finally ZnO:Al thin film layer was partially removed by mechanical cutting. Total 25 solar cells were formed on the substrate with 5×5 grid array format.

### EXAMPLE 3

A stainless steel sheet was formed to have 5 semi-cylindrical arrays with flattened areas between the semi-cylindrical areas. The radius of the semi-cylindrical area was 5 mm. The flattened area between the two semi-cylindrical areas was 6 mm. The substrate dimension is 100 mm length and 100 mm width. Grid array CIGS solar cells were formed on the substrate. The first step was to vacuum deposit a MoCu alloy back contact electrode followed by mechanical cutting to form patterns. A thin Cu layer was then deposited on the CuMo surface. Cu(InGa)Se₂ semiconductor layer was then formed by sequentially electroplating a stack of Cu/In/Ga/Se followed by annealing it at 550 C for 35 minutes under N₂ environment. CdS thin film was then deposited on the Cu(InGa)Se₂ surface by chemical deposition bath method. ZnO thin film was then vacuum deposited on the CdS surface followed by second mechanical cutting to form patterns. ZnO:Al thin film was then deposited on the ZnO surface and finally ZnO:Al was partially removed by mechanical cutting. Total 25 solar cells were formed on the substrate with 5×5 grid array format.

### REFERENCES

1. Hamda A. Al-Thani et al, “The deposition and characterization of Mo/CuInGaSe2/ZnO solar cell”, National Renewable Energy Laboratory report 7540-01-280-5500 (January 2001).

What is claimed:

1. A solar cell, wherein sunlight strikes its surface with maximum incident angle from sunrise to sunset, comprising:
a substrate;
a back contact electrode formed on the substrate;
a p-type semiconductor absorber layer formed on the back contact electrode
a n-type semiconductor layer formed on the p-type semiconductor absorber layer surface
a transparent conductive layer form on the n-type semiconductor layer surface
front electrodes

2. A multiple solar cells grid array unit, wherein the solar cells serially connected each other and sunlight strikes its surface with maximum incident angle from sunrise to sunset, comprising:
a substrate;
a back contact electrode formed on the substrate;
a p-type semiconductor absorber layer formed on the back contact electrode
a n-type semiconductor layer formed on the p-type semiconductor absorber layer surface
a transparent conductive layer form on the n-type semiconductor layer surface
front electrodes

3. A solar cell, wherein sunlight strikes its surface with maximum incident angle from sunrise to sunset, comprising:
a substrate;
a back contact electrode deposited on the substrate;
a junction layer
a transparent conductive layer
front electrodes

4. The solar cell of claim 1, wherein said the solar cell is at least one of the geometries selected from the group consisting of a) the solar cell comprises a semi-cylindrical area and flattened areas, wherein said the semi-cylindrical area is located in the center and the flattened areas adjoin to the right and left sides of the semi-cylindrical area; b) the solar cell comprises a hollowed semi-cylindrical area and flattened areas, wherein said the hollowed semi-cylindrical area is located in the center and the flattened areas adjoin to the right and left sides of the hollowed semi-cylindrical area; c) the solar cell comprises a top flattened semi-cylindrical area and flattened areas, wherein said the top flattened semi-cylindrical area is located in the center and the flattened areas adjoin to the right and left sides of the top flattened semi-cylindrical area.

5. The solar cell of claim 1, wherein the substrate includes at least one of the geometries selected from the group consisting of a) the substrate comprising a first surface and a second surface, wherein the first surface is a flattened area and the second surface is a semi-cylindrical area in the substrate, the two surfaces adjoin each other as first surface/second surface/first surface in the substrate; b) the substrate comprising a first surface and a second surface, wherein the first surface is a flattened area and the second surface is a hollowed semi-cylindrical area in the substrate, the two surfaces adjoin each other as first surface/second surface/first surface in the substrate; and c) the substrate comprising a first surface and a second surface, wherein said the first surface is a flattened area and the second surface is a top flattened semi-cylindrical area in the substrate, the two surfaces adjoin each other as first surface/second surface/first surface in the substrate.

6. The substrate of claim 5, wherein said the substrate includes at least one of the materials selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass.

7. The solar cell of claim 1, wherein the back contact electrode includes at least one stack of the materials selected from the group consisting of Molybdenum (Mo), chromium (Cr), Titanium (Ti), Tungsten (W), molybdenum/molybdenum-copper (Mo/Mo—Cu), molybdenum/molybdenum-indium (Mo/Mo—In), molybdenum/molybdenum-gallium (Mo/Mo—Ga), molybdenum/molybdenum-selenium (Mo/Mo—Se), chromium/chromium-copper (Cr/Cr—Cu), chromium/chromium-indium (Cr/Cr—In), chromium/chromium-gallium (Cr/Cr—Ga), chromium/chromium-selenium (Cr/Cr—Se), titanium/Titanium-copper (Ti/Ti—Cu), titanium/titanium-indium (Ti/Ti—In), titanium/titanium-gallium (Ti/Ti—Ga), titanium/titanium-selenium (Ti/Ti—Se), tungsten/tungsten-copper (W/W—Cu), tungsten/tungsten-indium (W/W—In), tungsten/tungsten-gallium (W/W—Ga), and tungsten/tungsten-selenium (W/W—Se).

8. The solar cell of claim 1, wherein the p-type semiconductor absorber layer formed on the back contact electrode includes at least one type selected from the group consisting of copper indium diselenide (CIS), copper-indium-gallium-diselenide (CIGS), and sulfur doped copper-indium-gallium-diselenide (CIGSS).

9. The solar cell of claim 8, wherein said the p-type semiconductor absorber layer is manufactured by vacuum deposition process including at least one of the processes consisting of a) co-evaporate Cu—In—Ga—Se in vacuum condition; b co-evaporate Cu—In—Se in vacuum condition, c) sequentially deposit Cu, In, Ga or their alloy followed by annealing it in a selenium vapor environment at a temperature between 400 C and 700 C. d) c) sequentially deposit Cu, In, Ga or their alloy followed by annealing it in a atmosphere containing selenium and sulfur vapors at a temperature between 400 C and 700 C.

10. The solar cell of claim 8, wherein said the p-type semiconductor absorber layer is manufactured by electroplating process including at least one of the processes consisting of a) sequentially electroplating Cu, In, Ga, Se or their alloy followed by annealing at a temperature between 400 C and 700 C, b) sequentially electroplate Cu, In, Ga or their alloy followed by annealing in a selenium vapor environment at a temperature between 400 C and 700 C, c) sequentially electroplate Cu, In, Se or their alloy followed by annealing in a selenium vapor environment at a temperature between 400 C and 700 C.

11. The n-type semiconductor layer of claim 1, wherein the n-type semiconductor layer includes cadmium sulfide (CdS).

12. The solar cell of claim 1, wherein the transparent conductive layer formed on the n-type semiconductor surface includes at least one material selected from the group consisting of transparent conducting oxide (ITO) thin film, ZnO thin film, and ZnO:Al thin film.

13. The solar cell of claim 1, wherein said a mirror is attached on its flattened area.

14. The multiple solar cells grid array unit of claim 2, wherein said the multiple solar cells comprising a first solar cell, a second solar cell, a third solar cell, a N−1 solar cell, and a N solar cell, each solar cell in said multiple solar cells comprising: a back contact electrode formed on substrate; a p-type semiconductor layer formed on the back contact electrode, a n-type semiconductor layer formed on p-type semiconductor layer, and a transparent conductive layer formed on n-type semiconductor layer, wherein the transparent conductive layer of the first solar cell in multiple solar cells is in serial electrical communication with the back contact electrode of the second solar cell in the multiple solar cells, the transparent conductive layer of the second solar cell in multiple solar cells is in serial electrical communication with the back contact electrode of the third solar cell in the multiple solar cells, and the transparent conductive layer of the order of the N−1 solar cell in multiple solar cells is in serial electrical communication with the back contact electrode of the order of the N solar cell in the multiple solar cells.

15. The multiple solar cells grid array unit of claim 14, wherein said the solar cell in the multiple solar cells grid array unit includes at least one of the geometries selected from the group consisting of a) a semi-cylindrical area and flattened areas, wherein the semi-cylindrical area is located in the center and the flattened areas adjoin to the right and left sides of the semi-cylindrical area; b) a hollowed semi-cylindrical area and flattened areas, wherein the hollowed semi-cylindrical area is located in the center and the flattened areas adjoin to the right and left sides of the hollowed semi-cylindrical area; and c) a top flattened semi-cylindrical area and flattened areas, wherein the top flattened semi-cylindrical area is located in the center and the flattened areas adjoin to the right and left sides of the top flattened semi-cylindrical area.

16. The multiple solar cells grid array unit of claim 2, wherein the substrate includes at least one of the geometries selected from the group consisting of 1) a flattened base with multiple semi-cylindrical area array on the flattened base, wherein said the substrate comprising a first surface and a second surface, the first surface is a flattened area and the second surface is a semi-cylindrical area in the substrate, the two surfaces adjoin each other as an array of first surface/second surface/first surface/second surface in the substrate. 2) a flattened base with multiple hollowed semi-cylindrical area array on the flattened base, wherein said the substrate comprising a first surface and a second surface, the first surface is a flattened area and the second surface is a hollowed semi-cylindrical area in the substrate, the two surfaces adjoin each other as an array of first surface/second surface/first surface/second surface in the substrate. 3) a flat base with multiple top flattened semi-cylindrical area array on the flat base, wherein said the substrate comprising a first surface and a second surface, the first surface is a flattened area and the second surface is a top flattened semi-cylindrical area in the substrate, the two surfaces adjoin each other as an array of first surface/second surface/first surface/second surface in the substrate.

17. The multiple solar cells grid array unit of claim 16, wherein said the substrate includes at least one of the materials selected from the group consisting of aluminosilicate glass, borosilicate glass, dichroic glass, germanium/semiconductor glass, silicate/fused silica glass, soda lime glass, quartz glass, chalcogenide/sulphide glass, fluoride glass, a glass-based phenolic, flint glass, plastic, aluminum, aluminum alloy, steel, stainless steel, and brass.

18. The multiple solar cells grid array unit of claim 2, wherein the back contact electrode includes at least one stack material selected from the group consisting of Molybdenum (Mo), chromium (Cr), Titanium (Ti), Tungsten (W), molybdenum/molybdenum-copper (Mo/Mo—Cu), molybdenum/molybdenum-indium (Mo/Mo—In), molybdenum/molybdenum-gallium (Mo/Mo—Ga), molybdenum/molybdenum-selenium (Mo/Mo—Se), chromium/chromium-copper (Cr/Cr—Cu), chromium/chromium-indium (Cr/Cr—In), chromium/chromium-gallium (Cr/Cr—Ga), chromium/chromium-selenium (Cr/Cr—Se), titanium/Titanium-copper (Ti/Ti—Cu), titanium/titanium-indium (Ti/Ti—In), titanium/titanium-gallium (Ti/Ti—Ga), titanium/titanium-selenium (Ti/Ti—Se), tungsten/tungsten-copper (W/W—Cu), tungsten/tungsten-indium (W/W—In), tungsten/tungsten-gallium (W/W—Ga), tungsten/tungsten-selenium (W/W—Se), TCO (transparent conducting oxide), ITO, and SnO2.

19. The multiple solar cells grid array unit of claim 2, wherein the p-type semiconductor absorber layer formed on the back contact electrode includes at least one material selected from the group consisting of copper indium diselenide (CIS), copper-indium-gallium-diselenide (CIGS), and sulfur doped copper-indium-gallium-diselenide (CIGSS).

20. The multiple solar cells grid array unit of claim 19, wherein the p-type semiconductor absorber layer is manufactured by vacuum deposition process including at least one of the processes consisting of a) co-evaporate Cu—In—Ga—Se in vacuum condition; and b) sequentially deposit Cu, In, Ga or their alloy using sputtering process followed by annealing in a selenium vapor environment at a temperature between 400 C and 700 C.

21. The multiple solar cells grid array unit of claim 19, wherein said the p-type semiconductor absorber layer is manufactured by electroplating process including at least one of the processes consisting of a) sequentially electroplating Cu, In, Ga, Se or their alloy followed by annealing at a temperature between 400 C and 700 C, and b) sequentially electroplate Cu, In, Ga or their alloy followed by annealing in a selenium vapor environment at a temperature between 400 C and 700 C.

22. The multiple solar cells grid array unit of claim 2, wherein the n-type semiconductor layer includes CdS.

23. The multiple solar cells grid array unit of claim 2, wherein the transparent conductive layer deposited on the n-type semiconductor surface includes at least one material selected from the group consisting of ITO thin film, ZnO thin film, and ZnO:Al thin film.

24. The solar cell of claim 3, wherein said the solar cell is at least one of the geometries selected from the group consisting of a) the solar cell comprises a semi-cylindrical area and flattened areas, wherein said the semi-cylindrical area is located in the center and the flattened areas adjoin to the right and left sides of the semi-cylindrical area; b) the solar cell comprises a hollowed semi-cylindrical area and flattened areas, wherein said the hollowed semi-cylindrical area is located in the center and the flattened areas adjoin to the right and left sides of the hollowed semi-cylindrical area; c) the solar cell comprises a top flattened semi-cylindrical area and flattened areas, wherein said the top flattened semi-cylindrical area is located in the center and the flattened areas adjoin to the right and left sides of the top flattened semi-cylindrical area.

25. The solar cell of claim 3, wherein the junction layer comprises a homojunction, a heterojunction, a hetero face junction, a buried homojunction, a p-i-n junction, and a tandem junction.

26. The solar cell of claim 24 includes p-n junction of CdTe-CdS layer, wherein said the CdTe is a p-type semiconductor layer and said the CdS is a n-type semiconductor layer.
